(19) United States
(12) Patent Application Publication
(10) Pub. No.: US 2015/0155846 A1
(43) Pub. Date: Jun. 4, 2015

(54) APPARATUS AND METHODS FOR WIRELESS COMMUNICATION

(71) Applicants: Wei He, Beijing (CN); Wenliang Qiao, Beijing (CN); Qingyu Guo, Beijing (CN)

(72) Inventors: Wei He, Beijing (CN); Wenliang Qiao, Beijing (CN); Qingyu Guo, Beijing (CN)

(73) Assignee: NOKIA CORPORATION, Espoo (FI)

(21) Appl. No.: 14/400,655

(22) PCT Filed: May 22, 2012
(86) PCT No.: PCT/CN2012/075905

§ 371 Date: Nov. 12, 2014

(51) Int. Cl. H03H 7/38; H01Q 5/335; H04W 88/06

(52) U.S. Cl. CPC H03H 7/38; H04W 88/06; H01Q 5/335; H03H 2007/386

(57) ABSTRACT

An apparatus comprising: a first resonant circuit configured to have an impedance at a first operational frequency band to impedance match a first radiator to radio circuitry, and to have an impedance at a second operational frequency band to impedance match a second radiator to the radio circuitry; a second resonant circuit configured to have an impedance at the first operational frequency band to impedance match the first radiator to the radio circuitry, and to have an impedance at the second operational frequency band to impedance match the second radiator to the radio circuitry; and a third resonant circuit configured to have an impedance at the first operational frequency band to impedance match the first radiator to the radio circuitry, and to have an impedance at the second operational frequency band to impedance match the second radiator to the radio circuitry.

### TECHNOLOGICAL FIELD

Embodiments of the present invention relate to apparatus and methods for wireless communication. In particular, they relate to apparatus and methods for wireless communication in electronic communication devices.

### BACKGROUND

Apparatus, such as electronic communication devices, usually include radio circuitry and an antenna for wireless communication. There are a relatively large number of different operational frequency bands (for example, long term evolution (LTE), global system for mobile communications (GSM), wideband code division multiple access (WCDMA)) and apparatus usually require several antennas (usually including one or more parasitic antennas) to operate in at least some of these operational frequency bands. However, this may disadvantageously increase the size and cost of the apparatus.

It would therefore be desirable to provide an alternative apparatus.

### BRIEF SUMMARY

According to various, but not necessarily ail, embodiments of the invention there is provided an apparatus comprising: a first resonant circuit configured to have an impedance at a first operational frequency band to impedance match a first radiator to radio circuitry, and to have an impedance at a second operational frequency band to impedance match a second radiator to the radio circuitry; a second resonant circuit configured to have an impedance at the first operational frequency band to impedance match the first radiator to the radio circuitry, and to have an impedance at the second operational frequency band to impedance match the second radiator to the radio circuitry; and a third resonant circuit configured to have an impedance at the first operational frequency band to impedance match the first radiator to the radio circuitry, and to have an impedance at the second operational frequency band to impedance match the second radiator to the radio circuitry.

The apparatus may be for wireless communication.

The first resonant circuit, the second resonant circuit and the third resonant circuit may be configured to resonate at frequencies different to the first and second operational frequency bands.

The first resonant circuit, the second resonant circuit and the third resonant circuit may be configured to resonate at frequencies between the first operational frequency band and the second operational frequency band.

The first resonant circuit and the third resonant circuit may be positioned in parallel between the radio circuitry and the first and second radiators, the second resonant circuit may be positioned in series between the radio circuitry and the first and second radiators.

The first resonant circuit may include an inductive reactance and a capacitive reactance in parallel, the second resonant circuit may include an inductive reactance and a capacitive reactance in series, and the third resonant circuit may include an inductive reactance and a capacitive reactance in series.

The first resonant circuit may include an inductive reactance and a capacitive reactance in series, the second resonant circuit may include an inductive reactance and a capacitive reactance in parallel, and the third resonant circuit may include an inductive reactance and a capacitive reactance in parallel.

The apparatus may further comprise an antenna coupled to the first, second and third resonant circuits via a feed point, the antenna may comprise a first radiator and a second radiator, the first radiator may define a first electrical path from the feed point and the second radiator may define a second electrical path from the feed point.

According to various, but not necessarily all, embodiments of the invention there is provided a module comprising an apparatus as described in any of the preceding paragraphs.

According to various, but not necessarily all, embodiments of the invention there is provided an electronic communication device comprising an apparatus as described in any of the preceding paragraphs.

According to various, but not necessarily all, embodiments of the invention there is provided a method comprising: providing a first resonant circuit configured to have an impedance at a first operational frequency band to impedance match a first radiator to radio circuitry, and to have an impedance at a second operational frequency band to impedance match a second radiator to the radio circuitry; providing a second resonant circuit configured to have an impedance at the first operational frequency band to impedance match the first radiator to the radio circuitry, and to have an impedance at the second operational frequency band to impedance match the second radiator to the radio circuitry; and providing a third resonant circuit configured to have an impedance at the first operational frequency band to impedance match the first radiator to the radio circuitry, and to have an impedance at the second operational frequency band to impedance match the second radiator to the radio circuitry.

The first resonant circuit, the second resonant circuit and the third resonant circuit may be configured to resonate at frequencies different to the first and second operational frequency bands.

The first resonant circuit, the second resonant circuit and the third resonant circuit may be configured to resonate at frequencies between the first operational frequency band and the second operational frequency band.

The method may further comprise positioning the first resonant circuit and the third resonant circuit in parallel between the radio circuitry and the first and second radiators, and positioning the second resonant circuit in series between the radio circuitry and the first and second radiators.

The first resonant circuit may include an inductive reactance and a capacitive reactance in parallel, the second resonant circuit may include an inductive reactance and a capacitive reactance in series, and the third resonant circuit may include an inductive reactance and a capacitive reactance in series.

The first resonant circuit may include an inductive reactance and a capacitive reactance in series, the second resonant circuit may include an inductive reactance and a capacitive reactance in parallel, and the third resonant circuit may include an inductive reactance and a capacitive reactance in parallel.

The method may further comprise providing an antenna coupled to the first, second and third resonant circuits via a feed point, the antenna may comprise a first radiator and a second radiator, the first radiator may define a first electrical path from the feed point and the second radiator may define a second electrical path from the feed point.

### BRIEF DESCRIPTION

For a better understanding of various examples of embodiments of the present invention reference will now be made by way of example only to the accompanying drawings in which:

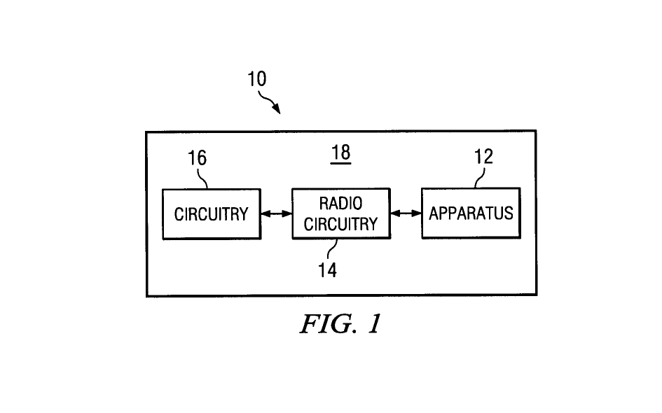

FIG. 1 illustrates a schematic diagram of an electronic communication device according to various embodiments of the invention;

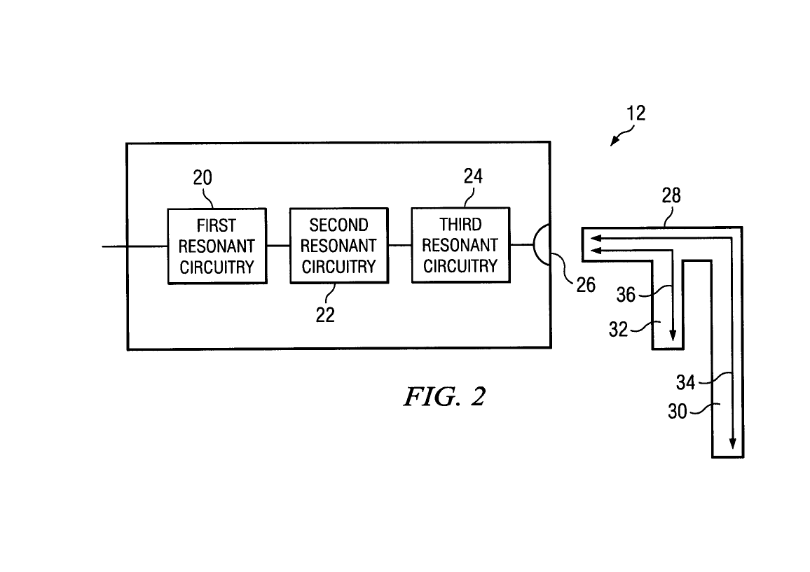

FIG. 2 illustrates a schematic diagram of an apparatus according to various embodiments of the invention;

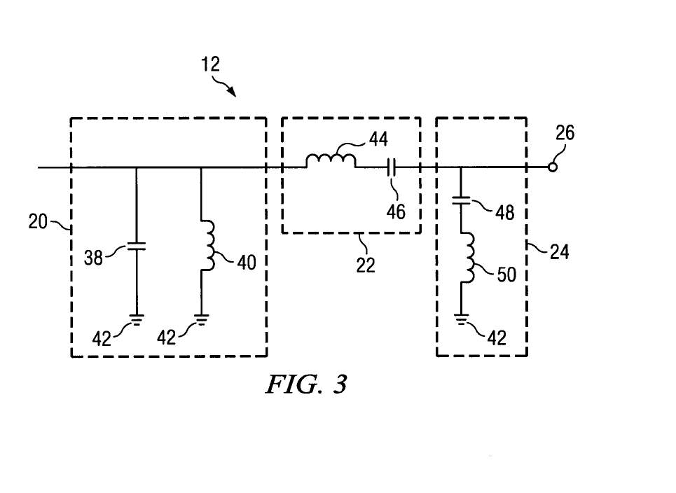

FIG. 3 illustrates a circuit diagram of an apparatus according to various embodiments of the invention;

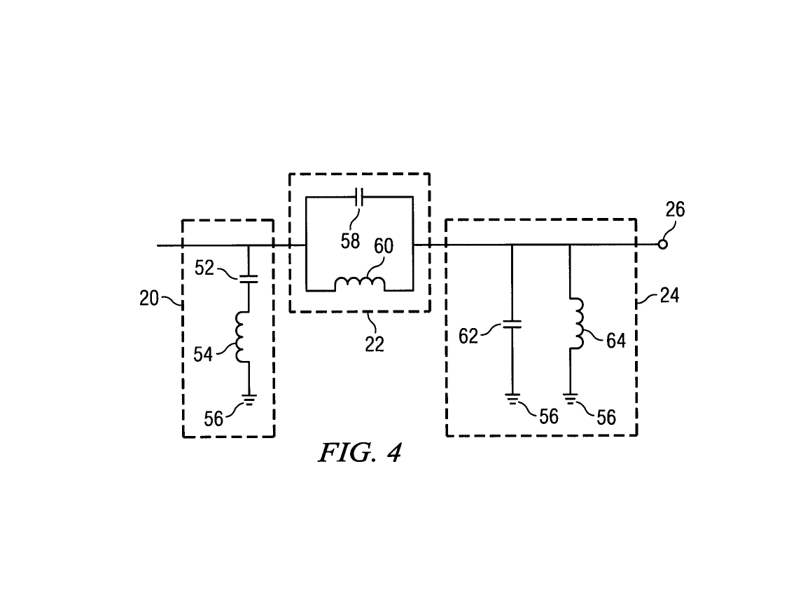

FIG. 4 illustrates a circuit diagram of another apparatus according to various embodiments of the invention; and

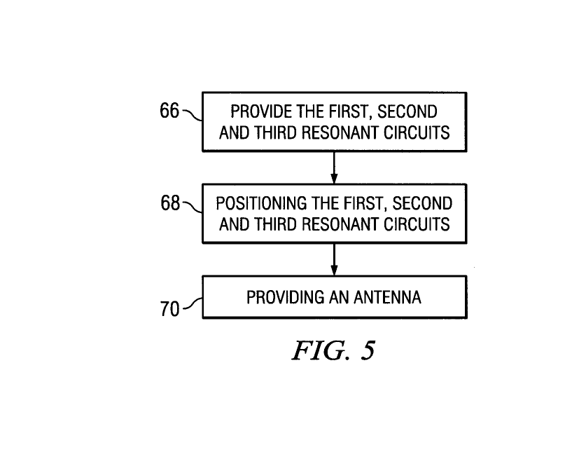

FIG. 5 illustrates a flow diagram of a method according to various embodiments of the invention.

### DETAILED DESCRIPTION

In the following description, the wording ‘connect’ and ‘couple’ and their derivatives mean operationally connected or coupled. It should be appreciated that any number or combination of intervening components can exist (including no intervening components). Additionally, it should be appreciated that the connection or coupling may be a physical galvanic connection and/or an electromagnetic connection.

FIGS. 2, 3 and 4 illustrate an apparatus 12 comprising: a first resonant circuit 20 configured to have an impedance at a first operational frequency band to impedance match a first radiator 30 to radio circuitry 14, and to have an impedance at a second operational frequency band to impedance match a second radiator 32 to the radio circuitry 14; a second resonant circuit 22 configured to have an impedance at the first operational frequency band to impedance match the first radiator 30 to the radio circuitry 14, and to have an impedance at the second operational frequency band to impedance match the second radiator 32 to the radio circuitry 14; and a third resonant circuit 24 configured to have an impedance at the first operational frequency band to impedance match the first radiator 30 to the radio circuitry 14, and to have an impedance at the second operational frequency band to impedance match the second radiator 32 to the radio circuitry 14.

In more detail, FIG. 1 illustrates an electronic communication device 10 which may be any apparatus such as a hand portable electronic communication device (for example, a mobile cellular telephone, a tablet computer, a laptop computer, a personal digital assistant or a hand held computer), a non-portable electronic device (for example, a personal computer or a base station for a cellular network), a portable multimedia device (for example, a music player, a video player, a game console and so on) or a module for such devices. As used here, ‘module’ refers to a unit or apparatus that excludes certain parts or components that would be added by an end manufacturer or a user.

The electronic communication device 10 comprises an apparatus 12, radio circuitry 14, circuitry 16 and a ground member 18. The apparatus 12 includes at least one antenna and is configured to transmit and receive, transmit only or receive only electromagnetic signals. The radio circuitry 14 is connected between the apparatus 12 and the circuitry 16 and may include a receiver and/or a transmitter and/or a transceiver. The circuitry 16 is operable to provide signals to, and/or receive signals from the radio circuitry 14.

The radio circuitry 14 and the apparatus 12 may be configured to operate in a plurality of operational frequency bands. For example, the operational frequency bands may include (but are not limited to) Long Term Evolution (LTE) (US) (734 to 746 MHz and 869 to 894 MHz), Long Term Evolution (LTE) (rest of the world) (791 to 821 MHz and 925 to 960 MHz), amplitude modulation (AM) radio (0.535-1.705 MHz); frequency modulation (FM) radio (76-108 MHz); Bluetooth (2400-2483.5 MHz); wireless local area network (WLAN) (2400-2483.5 MHz); hiper local area network (HLAN) (5150-5850 MHz); global positioning system (GPS) (1570.42-1580.42 MHz); US—Global system for mobile communications (US-GSM) 850 (824-894 MHz) and 1900 (1850-1990 MHz); European global system for mobile communications (EGSM) 900 (880-960 MHz) and 1800 (1710-1880 MHz); European wideband code division multiple access (EU-WCDMA) 900 (880-960 MHz); personal communications network (PCN/DCS) 1800 (1710-1880 MHz); US wideband code division multiple access (US-WCDMA) 1700 (transmit: 1710 to 1755 MHz, receive: 2110 to 2155 MHz) and 1900 (1850-1990 MHz); wideband code division multiple access (WCDMA) 2100 (transmit: 1920-1980 MHz, receive: 2110-2180 MHz); personal communications service (PCS) 1900 (1850-1990 MHz); time division synchronous code division multiple access (TD-SCDMA) (1900 MHz to 1920 MHz, 2010 MHz to 2025 MHz), ultra wideband (UWB) Lower (3100-4900 MHz); UWB Upper (6000-10600 MHz); digital video broadcasting-handheld (DVB-H) (470-702 MHz); DVB-H US (1670-1675 MHz); digital radio mondiale (DRM) (0.15-30 MHz); worldwide interoperability for microwave access (WiMax) (2300-2400 MHz, 2305-2360 MHz, 2496-2690 MHz, 3300-3400 MHz, 3400-3800 MHz, 5250-5875 MHz); digital audio broadcasting (DAB) (174.928-239.2 MHz, 1452.96-1490.62 MHz); radio frequency identification low frequency (RFID LF) (0.125-0.134 MHz); radio frequency identification high frequency (RFID HF) (13.56-13.56 MHz); radio frequency identification ultra high frequency (RFID UHF) (433 MHz, 865-956 MHz, 2450 MHz).

A frequency band over which an antenna can efficiently operate using a protocol is a frequency range where the return loss of the antenna is less than an operational threshold. For example, efficient operation may occur when the return loss of an antenna is better than (that is, less than) −4 dB or −6 dB.

In the embodiment where the electronic communication device 10 is a portable electronic communication device (such as a mobile phone), the circuitry 16 may include a processor, a memory and input/output devices such as an audio input device (a microphone for example), an audio output device (a loudspeaker for example) and a display.

The apparatus 12 and the electronic components that provide the radio circuitry 14 and the circuitry 16 may be interconnected via the ground member 18 (for example, a printed wiring board). The ground member 18 may be used as a ground plane for the apparatus 12 by using one or more layers of the printed wiring board 18. In other embodiments, some other conductive part of the electronic communication device 10 (a battery cover for example) may be used as the ground member 18 for the apparatus 12. In some embodiments, the ground member 18 may be formed from several conductive parts of the electronic communication device 10. The ground member 18 may be planar or non-planar.

FIG. 2 illustrates a schematic diagram of an apparatus 12 according to various embodiments of the invention. The apparatus 12 includes a first resonant circuit 20, a second resonant circuit 22, a third resonant circuit 24, a feed point 26 and an antenna 28.

The first resonant circuit 20 is connected between the radio circuitry 14 (not illustrated in FIG. 2) and the second resonant circuit 22. The first resonant circuit 20 may include any suitable reactive components and may include ‘lumped components’ such as inductors and capacitors, and/or ‘distributed components’ such as a planar microstrip and strip line microwave elements, and/or other radio frequency/microwave structures such as waveguides.

The second resonant circuit 22 is connected between the first resonant circuit 20 and the third resonant circuit 24. The second resonant circuit 22 may include any suitable reactive components and may include ‘lumped components’ such as inductors and capacitors, and/or ‘distributed components’ such as a planar microstrip and strip line microwave elements, and/or other radio frequency/microwave structures such as waveguides.

The third resonant circuit 24 is connected between the second resonant circuit 22 and the feed point 26. The third resonant circuit 24 may include any suitable reactive components and may include ‘lumped components’ such as inductors and capacitors, and/or ‘distributed components’ such as a planar microstrip and strip line microwave elements, and/or other radio frequency/microwave structures such as waveguides.

The feed point 26 is connected to the third resonant circuit 24 and is configured to receive the antenna 28.

The antenna 28 may be any suitable antenna and may be, for example, a planar inverted L antenna (PILA), a planar inverted F antenna (PIFA), a monopole antenna or a loop antenna as non-limiting examples. The antenna 28 includes a first radiator 30 and a second radiator 32 which are physically separate (but coupled either galvanically or electromagnetically) structures. The first radiator 30 defines a first electrical path 34 from the feed point 26 and has an electrical length that enables the first radiator 30 to resonate in a first operational frequency band (such as GSM 900). The second radiator 32 defines a second electrical path 36 from the feed point 26 and has an electrical length (different to the electrical length of the first radiator 30) that enables the second radiator 32 to resonate in a second operational frequency band (such as GSM 1800).

The first resonant circuit 20 is configured to have an impedance at the first operational frequency band to impedance match the first radiator 30 to the radio circuitry 14. The first resonant circuit 20 is also configured to have an impedance at the second operational frequency band to impedance match the second radiator 32 to the radio circuitry 14.

The second resonant circuit 22 is configured to have an impedance at the first operational frequency band to impedance match the first radiator 30 to the radio circuitry 14. The second resonant circuit 22 is also configured to have an impedance at the second operational frequency band to impedance match the second radiator 32 to the radio circuitry 14.

The third resonant circuit 24 is configured to have an impedance at the first operational frequency band to impedance match the first radiator 30 to the radio circuitry 14. The third resonant circuit 24 is also configured to have an impedance at the second operational frequency band to impedance match the second radiator 32 to the radio circuitry 14.

It should be appreciated that the term ‘impedance match’ includes examples where the apparatus 12 is configured such that the impedance of the apparatus 12 (including the antenna 28) is the same as the impedance of the radio circuitry 14. For example, the impedance of the radio circuitry 14 may be fifty ohms and the impedance of the apparatus 12 may be fifty ohms. The term ‘impedance match’ also includes examples where the apparatus 12 is configured such that the impedance of the apparatus 12 is brought towards (but not at) the impedance of the radio circuitry 14. For example, the impedance of the radio circuitry 14 may be fifty ohms and the impedance of the apparatus 12 is forty five ohms. The impedance of the radio circuitry 14 may also have an imaginary or reactance part (inductive or capacitive) in addition to the real or resistive part, and therefore the impedance may not lie on the purely resistive axis of a Smith Chart as is known in the art.

In various embodiments, the first resonant circuit 20, the second resonant circuit 22 and the third resonant circuit 24 are configured to resonate at frequencies different to the first and second operational frequency bands. Consequently, the first resonant circuit 20, the second resonant circuit 22 and the third resonant circuit 24 are capacitive or inductive at the first and second operational frequency bands. In some examples, the first resonant circuit 20, the second resonant circuit 22 and the third resonant circuit 24 are configured to resonate at frequencies between the first operational frequency band and the second operational frequency band. For example, where the first operational frequency band is GSM 900 and the second operational frequency band is GSM 1800, the resonant frequencies of the first, second and third resonant circuits 20, 22, 24 are between 900 MHz and 1800 MHz.

Various embodiments of the present invention provide an advantage in that the apparatus 12 is relatively compact (for example, the apparatus 12 does not include any parasitic antennas) and is configured to operate in two separate operational frequency bands. This may advantageously result in a relatively small electronic device 10 that is able to operate in a broader range of operational frequencies.

FIG. 3 illustrates a circuit diagram of an apparatus 12 according to various embodiments of the invention. The apparatus illustrated in FIG. 3 is similar to the apparatus illustrated in FIG. 2 and where the features are similar, the same reference numerals are used.

The first resonant circuit 20 includes a capacitor 38 and an inductor 40 in parallel with one another, and in parallel between the radio circuitry 14 (not illustrated in FIG. 3 for clarity) and the feed point 26 and coupled to ground 42.

The second resonant circuit 22 includes an inductor 44 and a capacitor 46 in series with one another, and in series between the radio circuitry 14 and the feed point 26.

The third resonant circuit 24 includes a capacitor 48 and an inductor 50 in series with one another, and in parallel between the radio circuitry 14 and the feed point 26 and coupled to ground 42.

The first, second and third resonant circuits 20, 22, 24 are configured so that at the first (low) operational frequency band, the first resonant circuit 20 has an inductive impedance, the second resonant circuit 22 has a capacitive impedance, and the third resonant circuit 24 has a capacitive impedance. The first, second and third resonant circuits 20, 22, 24 are also configured so that at the second (high) operational frequency band, the first resonant circuit 20 has a capacitive impedance, the second resonant circuit 22 has an inductive impedance, and the third resonant circuit 24 has an inductive impedance. The values of the reactive components 38, 40, 44, 46, 48, 50 of the first, second and third resonant circuits 20, 22, 24 are selected so that at the first and second operational frequency bands, they have the above mentioned impedances that result in impedance matching between the antenna 28 and the radio circuitry 14.

FIG. 4 illustrates a circuit diagram of another apparatus 12 according to various embodiments of the invention. The apparatus illustrated in FIG. 4 is similar to the apparatus illustrated in FIG. 2 and where the features are similar, the same reference numerals are used.

The first resonant circuit 20 includes a capacitor 52 and an inductor 54 in series with one another, and in parallel between the radio circuitry 14 (not illustrated in FIG. 4 for clarity) and the feed point 26 and coupled to ground 56.

The second resonant circuit 22 includes a capacitor 58 and an inductor 60 in parallel with one another, and in series between the radio circuitry 14 and the feed point 26.

The third resonant circuit 24 includes a capacitor 62 and an inductor 64 in parallel with one another, and in parallel between the radio circuitry 14 and the feed point 26 and coupled to ground 56.

The first, second and third resonant circuits 20, 22, 24 are configured so that at the first (low) operational frequency band, the first resonant circuit 20 has a capacitive impedance, the second resonant circuit 22 has an inductive impedance, and the third resonant circuit 24 has an inductive impedance. The first, second and third resonant circuits 20, 22, 24 are also configured so that at the second (high) operational frequency band, the first resonant circuit 20 has an inductive impedance, the second resonant circuit 22 has a capacitive impedance, and the third resonant circuit 24 has a capacitive impedance. The values of the reactive components 52, 54, 58, 60, 62, 64 of the first, second and third resonant circuits 20, 22, 24 are selected so that at the first and second operational frequency bands, they have the above mentioned impedances that result in impedance matching between the antenna 28 and the radio circuitry 14.

FIG. 5 illustrates a flow diagram of a method of manufacturing an apparatus 12 according to various embodiments of the invention. At block 66, the method includes providing the first resonant circuit 20, the second resonant circuit 22 and the third resonant circuit 24. At block 68, the method includes positioning the first resonant circuit 20, the second resonant circuit 22, and the third resonant circuit 24. For example, the first, second and third resonant circuits 20, 22, 24 may be positioned as illustrated in FIG. 3 or in FIG. 4. At block 70, the method includes providing the antenna 28 and coupling the antenna 28 to the feed point 26.

The blocks illustrated in the FIG. 5 may represent steps in a method and/or sections of code in a computer program. For example, a controller may read the computer program and control machinery to perform the method illustrated in FIG. 5. The illustration of a particular order to the blocks does not necessarily imply that there is a required or preferred order for the blocks and the order and arrangement of the block may be varied. Furthermore, it may be possible for some blocks to be omitted.

Although embodiments of the present invention have been described in the preceding paragraphs with reference to various examples, it should be appreciated that modifications to the examples given can be made without departing from the scope of the invention as claimed.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

1-16. (canceled)

17. An apparatus comprising:
a first resonant circuit configured to have an impedance at a first operational frequency band to impedance match a first radiator to radio circuitry, and to have an impedance at a second operational frequency band to impedance match a second radiator to the radio circuitry;
a second resonant circuit configured to have an impedance at the first operational frequency band to impedance match the first radiator to the radio circuitry, and to have an impedance at the second operational frequency band to impedance match the second radiator to the radio circuitry; and
a third resonant circuit configured to have an impedance at the first operational frequency band to impedance match the first radiator to the radio circuitry, and to have an impedance at the second operational frequency band to impedance match the second radiator to the radio circuitry.

18. An apparatus as claimed in claim 17, wherein the first resonant circuit, the second resonant circuit and the third resonant circuit are configured to resonate at frequencies different to the first and second operational frequency bands.

19. An apparatus as claimed in claim 17, wherein the first resonant circuit, the second resonant circuit and the third resonant circuit are configured to resonate at frequencies between the first operational frequency band and the second operational frequency band.

20. An apparatus as claimed in claim 17, wherein the first resonant circuit and the third resonant circuit are positioned in parallel between the radio circuitry and the first and second radiators, the second resonant circuit being positioned in series between the radio circuitry and the first and second radiators.

21. An apparatus as claimed in claim 20, wherein the first resonant circuit includes an inductive reactance and a capacitive reactance in parallel, the second resonant circuit includes an inductive reactance and a capacitive reactance in series, and the third resonant circuit includes an inductive reactance and a capacitive reactance in series.

22. An apparatus as claimed in claim 20, wherein the first resonant circuit includes an inductive reactance and a capacitive reactance in series, the second resonant circuit includes an inductive reactance and a capacitive reactance in parallel, and the third resonant circuit includes an inductive reactance and a capacitive reactance in parallel.

23. An apparatus as claimed in claim 17, further comprising an antenna coupled to the first, second and third resonant circuits via a feed point, the antenna comprising a first radiator and a second radiator, the first radiator defining a first electrical path from the feed point and the second radiator defining a second electrical path from the feed point.

24. A module comprising an apparatus as claimed in claim 17.

25. An electronic communication device comprising an apparatus as claimed in claim 17.

26. A method comprising:
providing a first resonant circuit configured to have an impedance at a first operational frequency band to impedance match a first radiator to radio circuitry, and to have an impedance at a second operational frequency band to impedance match a second radiator to the radio circuitry;
providing a second resonant circuit configured to have an impedance at the first operational frequency band to impedance match the first radiator to the radio circuitry, and to have an impedance at the second operational frequency band to impedance match the second radiator to the radio circuitry; and
providing a third resonant circuit configured to have an impedance at the first operational frequency band to impedance match the first radiator to the radio circuitry, and to have an impedance at the second operational frequency band to impedance match the second radiator to the radio circuitry.

27. A method as claimed in claim 26, wherein the first resonant circuit, the second resonant circuit and the third resonant circuit are configured to resonate at frequencies different to the first and second operational frequency bands.

28. A method as claimed in claim 26, wherein the first resonant circuit, the second resonant circuit and the third resonant circuit are configured to resonate at frequencies between the first operational frequency band and the second operational frequency band.

29. A method as claimed in claim 26, further comprising positioning the first resonant circuit and the third resonant circuit in parallel between the radio circuitry and the first and second radiators, and positioning the second resonant circuit in series between the radio circuitry and the first and second radiators.

30. A method as claimed in claim 29, wherein the first resonant circuit includes an inductive reactance and a capacitive reactance in parallel, the second resonant circuit includes an inductive reactance and a capacitive reactance in series, and the third resonant circuit includes an inductive reactance and a capacitive reactance in series.

31. A method as claimed in claim 29, wherein the first resonant circuit includes an inductive reactance and a capacitive reactance in series, the second resonant circuit includes an inductive reactance and a capacitive reactance in parallel, and the third resonant circuit includes an inductive reactance and a capacitive reactance in parallel.

32. A method as claimed in claim 26, further comprising providing an antenna coupled to the first, second and third resonant circuits via a feed point, the antenna comprising a first radiator and a second radiator, the first radiator defining a first electrical path from the feed point and the second radiator defining a second electrical path from the feed point.
